(19) United States
(12) Patent Application Publication
(10) Pub. No.: US 2009/0090489 A1
(43) Pub. Date: Apr. 9, 2009

(54) Water-cooling heat-dissipating module of electronic apparatus

(75) Inventor: Kuei-Feng Chiang, Taipei County (TW)

Correspondence Address: BACON & THOMAS, PLLC, 625 SLATERS LANE, FOURTH FLOOR, ALEXANDRIA, VA, 22314-1176, US

(73) Assignee: ASIA VITAL COMPONENTS CO., LTD., Taipei County (TW)

(21) Appl. No.: 11/905,866

(22) Filed: Oct. 5, 2007

(51) Int. Cl. F28F 7/00; F25D 23/12; H05K 7/20; F28D 15/00; F28D 21/00

(52) U.S. Cl. 165/104.33; 361/701; 62/259.2; 165/121

(57) ABSTRACT

A water-cooling heat-dissipating module of an electronic apparatus includes a heat-conducting unit, a driving unit and a dissipating unit. The heat-conducting unit has a function of conducting a heat source. The dissipating unit has a function of dissipating the heat of a fluid. The driving unit has a function of driving the fluid. Via the driving unit, the fluid can be rapidly introduced into or drained out of each unit for circulation, thereby achieving the heat-dissipating effect.

### BACKGROUND OF THE INVENTION

1. Field of the Invention

The present invention relates to a water-cooling heat-dissipating module of an electronic apparatus, and in particular to a water-cooling heat-dissipating module of an electronic apparatus, thereby accelerating the cooling of a fluid so as to facilitate the heat dissipation.

2. Description of Prior Art

With the progress of precise technologies, in order to execute some preset functions, the interior of a computer casing may be provided with some components, such as a central processing unit (CPU), displaying card, disk drive, sound effect card or the like. Some of these installed components have to consume a larger amount of heat in operation, such as the central processing unit (referred to as CPU) and displaying card (referred to as VGA1, VGA2). Such kind of heat-generating components need to forcibly dissipate the heat thereof generated in operation, thereby maintaining the normal operation of the components. In the current market, there is a tendency toward the compactness of the products. Since the processing speed of an information apparatus needs to be higher and higher, a chip set is thus developed, which is more complicated in structure and generates relatively high pulses in operation. As a result, excessive amount of heat is inevitably generated. In view of this problem, since the conventional heat-dissipating module having heat-dissipating fins and heat-dissipating fans gradually becomes insufficient to complete the heat dissipation, a water-cooling heat-dissipating module is currently used.

In order to solve the problem of the overheated elements of a computer, the most direct and easiest way is to mount a heat-dissipating device on the elements of the computer. For example, a water-cooling heat-dissipating device dedicated to a computer can be used. Via this arrangement, the large amount of heat generated by a heat-generating source can be dissipated to the outside, thereby protecting the temperature of the elements of the computer from becoming too high and thus keeping the stability in the operation of the elements of the computer. In view of the limited space, conventionally, a plurality of water blocks is mounted on various heat-generating elements. Especially, the water blocks are mounted directly on south bridge chips and north bridge chips, and soft conduits are used to interconnect the water blocks between the south and north bridge chips. Finally, an external heat dissipator and a pump are provided to form a heat-dissipating system. With the operation of the pump, the cooling liquid can be compressed to flow in each water block, thereby performing a heat-exchanging action. However, since the above-mentioned heat-dissipating system is constituted of individual heat-dissipating assemblies, it is not an independent heat-dissipating structure that a plurality of soft conduits is used to interconnect individual components. Since the heat-bearing capacity of the soft conduit is bad, after a long-term use in a hot environment, the connecting portion between the soft conduit and the water block becomes loose. As a result, the cooling liquid flowing in the soft conduit may leak to the outside through the old and broken conduit, causing the electronic element to get damaged. Further, because of the poor connection of conduits, the cooling liquid may evaporate gradually and external air may enter the interior of the conduits easily. When the cooling liquid within the water-cooling system gradually evaporates and a lot of air exists in the conduits, the heat-dissipating efficiency will be deteriorated greatly. On the other hand, insufficient heat-dissipating medium may cause a danger in use. The above-mentioned problems have already been the primary issues for those skilled in this art.

Therefore, in view of the above-mentioned drawbacks of prior art, the inventor attempts to overcome the above problems with the cooperation of associated manufactures in this field.

### SUMMARY OF THE INVENTION

Therefore, in view of the above-mentioned drawbacks of prior art, the inventor collects related information, considers all the aspects and thus proposes the present invention to overcome the above problems based on his expert experience and deliberate researches.

The object of the present invention is to provide a water-cooling heat-dissipating module, in which water pipes are used to connect a driving unit, a heat-conducting unit and a dissipating unit. A fluid circulates in the above three components. Via the driving unit, the fluid is guided from the dissipating unit to flow into the heat-conducting unit. Further, the heat-conducting unit is provided on a heat-generating source. With the fluid being injected into the heat-conducting unit, the temperature of the heat-conducting unit can be lowered. At the same time, the remaining heat source can be carried away. The heat source is carried by the fluid and thus is guided back to the dissipating unit. The dissipating unit reduces the temperature of the fluid. The fluid whose temperature is reduced continues to circulate via the driving unit. An accommodating layer is provided in the top of the driving unit of the heat-dissipating module. The accommodating layer is provided with a water-guiding fan constituted of a plurality of fan blades. A water-guiding notch is provided at an adjacent position between each fan blade. Via this arrangement, when the water-guiding fan starts to rotate, the fluid flowing into the driving unit is delivered by a conduit connected with the water pipe, and then is injected into the heat-conducting unit. The fluid passes through a closed water-receiving space that is formed of a cover and chassis provided in the heat-conducting unit. After the fluid circulates in the closed water-receiving space continuously, the fluid drains out of the heat-conducting unit through a draining pipe of the cover, and is then delivered back to the dissipating unit via the water pipe for the subsequent cooling, thereby performing a cooling action continuously to the heat-dissipating module. Each unit is connected one another by means of the water pipes. In this way, the heat-generating source can be dissipated smoothly via the heat-dissipating module, thereby achieving the object of heat dissipation.

### BRIEF DESCRIPTION OF THE DRAWINGS

FIG. 1 is an exploded perspective view of a preferred embodiment of the present invention;

FIG. 2 is a cross-sectional view showing the heat-conducting unit B of the preferred embodiment of the present invention;

FIG. 3 is a partial view showing the action of the water-guiding fan of the preferred embodiment of the present invention;

FIG. 4 is a cross-sectional perspective view showing the water-guiding body of the preferred embodiment of the present invention;

FIG. 5 is a schematic view showing an arrangement of the preferred embodiment of the present invention;

FIG. 6 is a schematic view showing another arrangement of the preferred embodiment of the present invention; and

FIG. 7 is a schematic view showing still another arrangement of the preferred embodiment of the present invention.

### DETAILED DESCRIPTION OF THE INVENTION

In order to achieve the above objects and effects, the special technical measures and structures utilized in the present invention will be explained in detail with reference to the accompanying drawings in terms of characteristics and functions of preferred embodiments of the present invention.

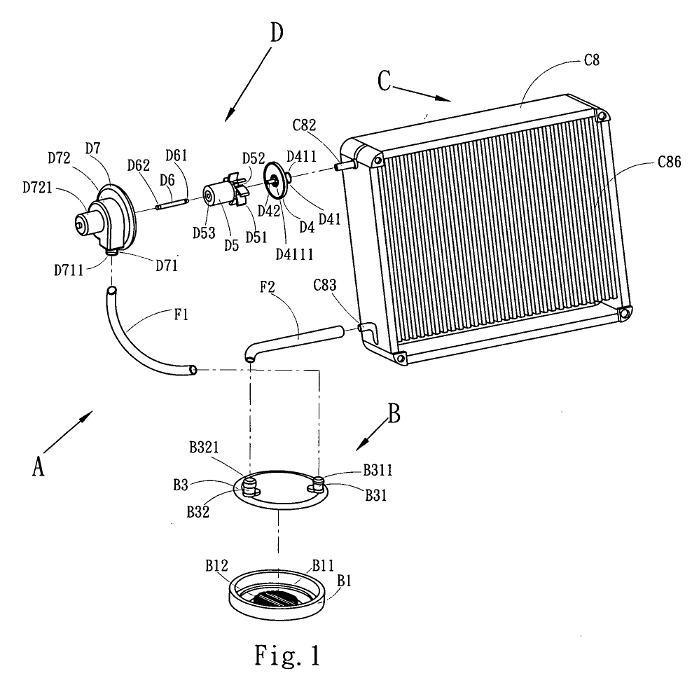

With reference to FIG. 1, it is an exploded perspective view of a preferred embodiment of the present invention. As shown in this figure, a heat-dissipating module A comprises three major units as follows.

A heat-conducting unit A comprises a chassis B1 and a cover B3.

A dissipating unit C comprises a water tank C8, a draining hole C82, a water-injecting hole C83 and heat-dissipating fins C86.

The driving unit D comprises a water-guiding body D7, a spindle D6, a water-guiding fan D5 and a base D4.

Each of the units is interconnected to one another by means of a water pipe F1 and a water pipe F2.

The chassis B1 has a water-receiving space B11, and the chassis B1 is provided with a plurality of projecting heat-dissipating portions B12.

The chassis B1 is provided at a lower end of the cover B3. The cover B3 is used to cover the chassis, so that the closed water-receiving space B11 is formed therebetween to allow a fluid to circulate in the water-receiving space B11.

An upper end of the cover B3 is provided with a water-injecting pipe B31 and a draining pipe B32. The water-injecting pipe B31 is connected to one end of the water pipe F1. The other end of the water pipe F1 is connected with a water-guiding pipe D71 provided at the lower end of the water-guiding body D7. The water-injecting pipe B31 is connected with the water-guiding pipe D71 via the water pipe F1.

A front end D61 of the spindle D6 penetrates through a central hole D53 of the water-guiding fan D5, and is then fixedly combined with a spindle seat D42 of the water-guiding fan provided on the base D4.

The water tank C8 is constituted of heat-dissipating fins C86 and heat-conducting pipes. The interior of the heat-conducting pipe has at least one water-receiving space (not shown). The fluid carrying heat energy can flow through the water-receiving space to transfer the heat to the outside via the heat-dissipating fins C86, thereby dissipating the heat of the fluid.

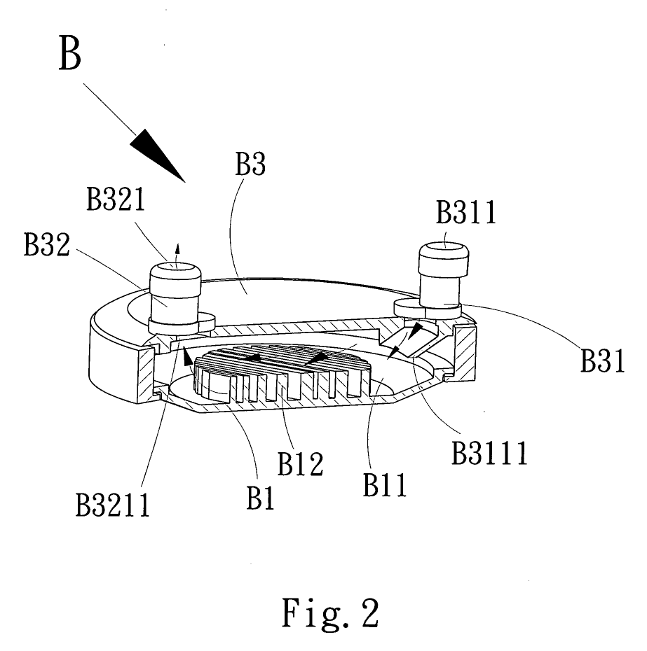

With reference to FIG. 2, it is a perspective cross-sectional view showing the heat-conducting unit B of the preferred embodiment of the present invention. As shown in this figure, the fluid flows into the heat-conducting unit B via the water-injecting pipe B31. The fluid flows through the water-injecting holes B311 and then flows into the water-receiving space B11 formed between the underlying chassis B1 and the cover B3. The water-injecting hole B311 is provided with a buffer channel B3111 that allows the fluid to enter the water-receiving space B11 slowly. After the fluid circulates in the water-receiving space B11, the fluid flows toward the draining hole B3211 provided at the lower end of the cover B3, and then flows into the draining pipe B32 provided at the upper end of the cover B3. Finally, the fluid flows out of the heat-conducting unit B via the draining hole B321.

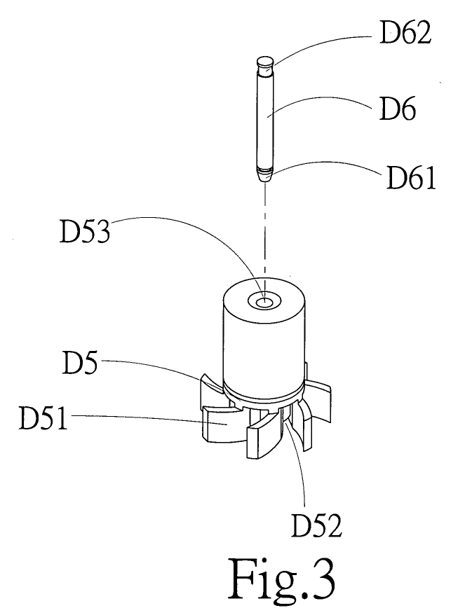

With reference to FIG. 3, it is a partial view showing the action of the water-guiding fan of the preferred embodiment of the present invention. As shown in this figure, the front end D61 of the spindle D6 penetrates through the inner hole D53 of the water-guiding fan D5 and is then combined with the water-guiding fan D5. When the fan blades D51 of the water-guiding fan D5 rotate, the fluid is injected between the neighboring fan blades D51 via the water-guiding notch D52, the fan blades D51 can guide the flowing direction of the fluid.

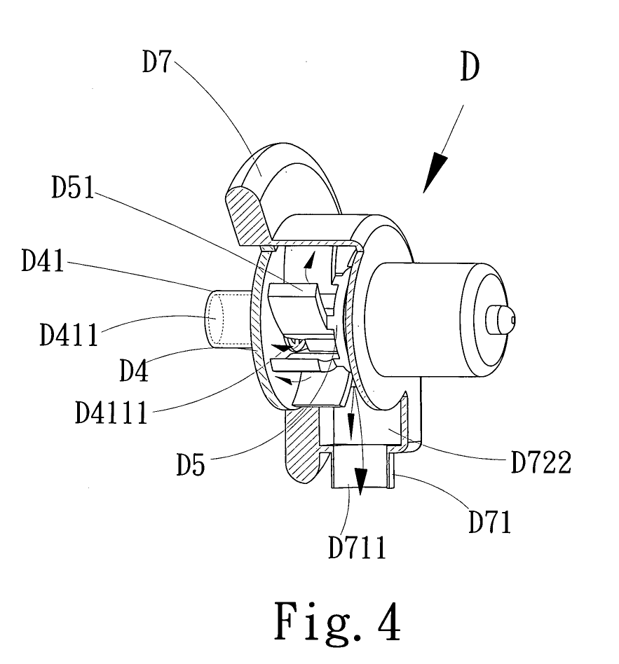

With reference to FIG. 4, it is a cross-sectional perspective view showing the driving unit D of the preferred embodiment of the present invention. As shown in this figure, the fluid is injected from the water-injecting pipe D41 provided at the lower end of the base D4, and is then injected into the bottom of the water-guiding body D7 via a water-delivering hole D411 provided at the upper end of the base D4. Via the blades D51 of the rotating water-guiding fan D5, the fluid is guided to flow into the water-guiding hole D711 of the water-guiding body D7, and subsequently flow into the water-injecting pipe B31 provided at the upper end of the underlying cover B3 (as shown in FIG. 2).

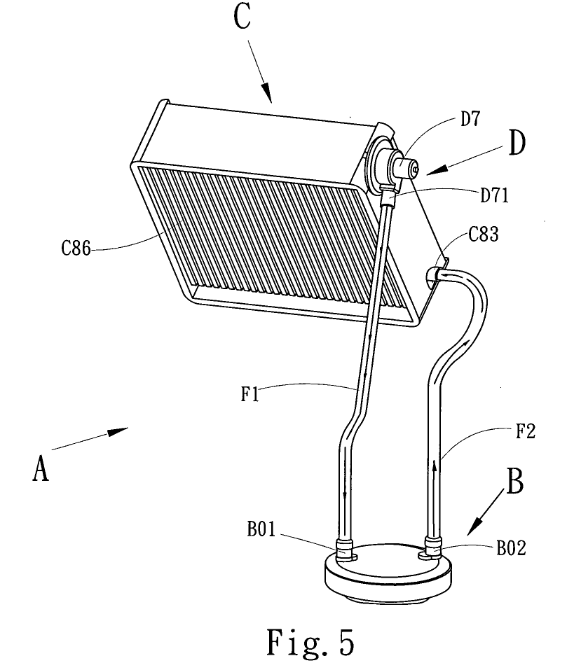

With reference to FIG. 5, it is a schematic view showing an arrangement of the preferred embodiment of the present invention. As shown in this figure, a draining pipe C82 (not shown) provided on the water tank C8 of the dissipating unit C is combined with the driving unit D. One end of the water pipe F1 is connected with the water-guiding pipe D71 provided on the driving unit D, and the other end of the water pipe F1 is connected with the water-injecting pipe B01 of the heat-conducting unit B. Via this arrangement, the fluid can enter the heat-conducting unit b to circulate therein. The draining pipe B02 of the heat-conducting unit B is used to drain the fluid out of the heat-conducting unit B. One end of the water pipe F2 is connected with the draining pipe B02, and the other end of the water pipe F2 is connected with the water-injecting pipe C83 provided on the water tank C8 of the dissipating unit C. In this way, the fluid carrying the heat energy is delivered back to the dissipating unit C via the water pipe F2, thereby performing the heat dissipation.

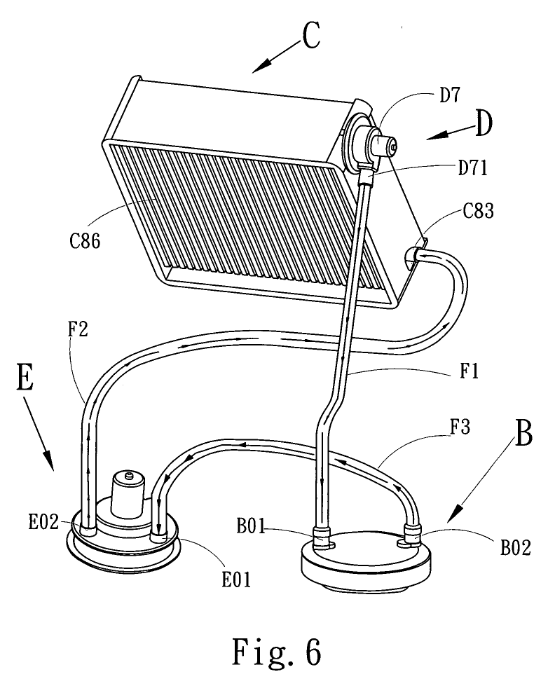

With reference to FIG. 6, it is a schematic view showing another arrangement of the preferred embodiment of the present invention. As shown in this figure, a water-injecting pipe C82 (not shown) provided on the water tank C8 of the dissipating unit C is combined with the driving unit D. One end of the water pipe F1 is connected with the water-guiding pipe D71 provided on the driving unit D, and the other end of the water pipe F1 is connected with the water-injecting pipe B01 provided at the upper end of the heat-conducting unit B. Via this arrangement, the fluid can enter the heat-conducting unit B. Via the driving unit D, the fluid can be guided to the outside of the driving unit D through the water-guiding hole D711. Then, via the water pipe F1 connected with the driving unit D, the fluid can be guided into the heat-conducting unit B to circulate therein. The fluid drains out of the heat-conducting unit B from the heat-conducting unit B via the draining pipe B02. After the water-injecting pipe E01 provided on the heat-conducting unit E is connected between the heat-conducting unit B and the heat-conducting unit E via the water pipe F3, the fluid can be delivered into the heat-conducting unit E via the water pipe F3. After the fluid flows in the heat-conducting unit E and circulates therein, the fluid is pressurized via the water-guiding fan within the heat-conducting unit E, the fluid drains out of the heat-conducting unit E via the draining pipe E02 provided at the upper end of the heat-dissipating unit E. One end of the water pipe F2 is connected with the draining pipe E02, and the other end of the water pipe F2 is connected with the water-injecting pipe C83 provided in the dissipating unit C. The fluid carrying the heat energy is delivered back to the dissipating unit C via the water pipe F2, thereby dissipating the heat and cooling down. After the fluid is cooled down, the fluid continues to circulate in the heat-dissipating module A. When the number of the heat sources in the electronic apparatus is increased, a plurality of sets of heat-conducting units B or heat-conducting units E can be additionally provided, thereby increasing the heat-dissipating effect.

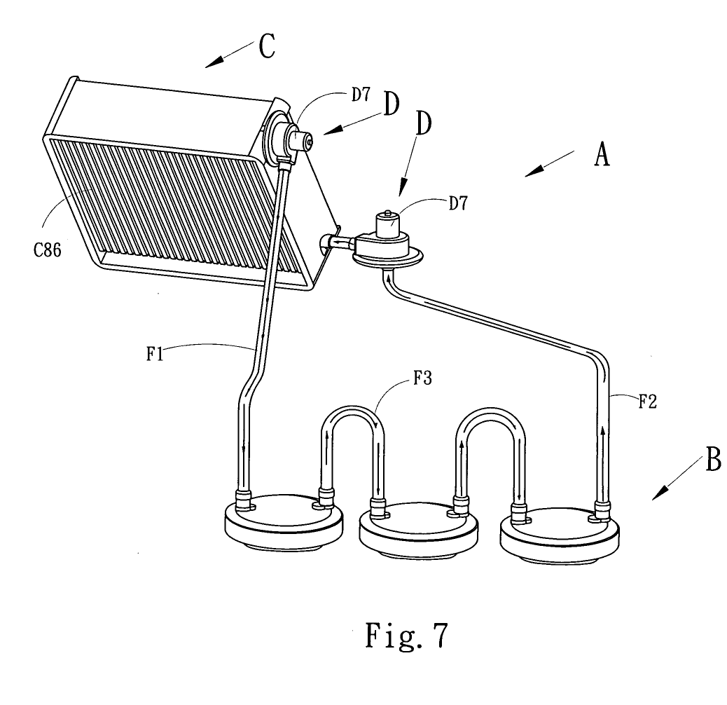

With reference to FIG. 7, it is a schematic view showing still another arrangement of the preferred embodiment of the present invention. As shown in this figure, a further driving unit D is provided in the water-injecting pipe C83 of the water tank C8 of the dissipating unit C, thereby increasing the flowing efficiency of the fluid. The heat-dissipating module A is provided therein with a plurality of heat-conducting units B. Each of the heat-conducting units B is connected to one another via the water pipes F3, so that the fluid can pass through each heat-conducting unit B sequentially. Finally, the water pipe F2 is connected with a driving unit D provided at a front end of the water-injecting pipe C83 of the water tank C8 of the dissipating unit C. After being pressurized via the driving unit D, the fluid is delivered back to the dissipating unit C.

Although the present invention has been described with reference to the foregoing preferred embodiments, it will be understood that the invention is not limited to the details thereof. Various equivalent variations and modifications with regard to the construction or arrangement thereof can still occur to those skilled in this art in view of the teachings of the present invention. Thus, all such variations and equivalent modifications are also embraced within the scope of the invention as defined in the appended claims.

In comparison with the prior art, the present invention really has the following advantages.

(I) More Rapid Dissipation of the Heat of the Heat-Generating Element

Since the chassis B1 of the heat-conducting unit B is brought into direct contact with the heat-generating sources, the heat energy of the heat-generating sources can be conducted to the chassis B1 of the heat-conducting unit B directly and is then transferred to internal heat-dissipating portions B12. Since the interior of the chassis B1 is filled with the fluid and the heat-dissipating portions B12 can increase the contacting area between the chassis B1 and the water, large amount of the heat energy of the heat-generating sources can be dissipated very rapidly.

(II) More Rapid Water Circulation

The heat-dissipating module A is provided with the driving unit D, in which a driving unit D5 is provided. When the interior of the heat-conducting unit B is filled with water, the fluid can be guided very fast from the outside into the heat-conducting unit B to flow therein due to the rotation of the water-guiding fan D5. In this way, the fluid can be drained out or introduced into the heat-conducting unit B more efficiently. At the same time, the complex design of the channels within the heat-conducting unit B can be reduced.

(III) More Efficient Heat Dissipation

With the interconnection of the driving unit D5, the water pipe F1, the water pipe F2, the heat-conducting unit B and the dissipating unit C, the fluid can circulate in the heat-dissipating module A. Via the fluid, the heat source can be conducted to the outside of the heat-conducting unit B. Via the water pipe F2, the heat source is carried to the dissipating unit C at a farther end. The fluid is cooled down in the dissipating unit C, so that the heat sources may not concentrate on the same position to increase the temperature of the each heat-generating source. With the continuous circulation of the cooled fluid in the heat-dissipating module A, the heat energy can be carried away from the heat-generating source. In view of a plurality of heat-generating sources in the electronic apparatus, a plurality of sets of heat-conducting units B can be additionally provided to perform the cooling, circulating and heat-dissipating actions of the fluid together.

According to the above, the water-cooling heat-dissipating module of an electronic apparatus of the present invention really achieves the desired effects and objects. Further, the present invention indeed has novelty and inventive steps and thus conforms to the requirements for a utility model patent.

What is claimed is:

1. A water-cooling heat-dissipating module of an electronic apparatus, comprising:
a heat-conducting unit having a chassis and a cover, the chassis and the cover being combined with each other to form a water-receiving space therebetween, the cover adapted to cover on the chassis, an upper end of the cover being provided with a water-injecting pipe and a draining pipe for draining a fluid out of the water-receiving space;
a driving unit having a water-guiding body, the water-guiding body being provided with a water-guiding hole, the water-guiding body being provided with an accommodating layer, the accommodating layer receiving a spindle and a water-guiding fan therein, the water-guiding fan being provided therein with a shaft hole for allowing the spindle to penetrate therethrough, the water-guiding fan having a plurality of fan blades received in the water-guiding body, a base being provided at a side end of the water-guiding body, a water-injecting pipe being provided on the base, the fluid entering the water-guiding body via the water-injecting pipe; and
a dissipating unit having at least one water-receiving space, at least one draining pipe and at least one water-injecting pipe, the draining pipe being connected with the water-guiding body.

2. The water-cooling heat-dissipating module of an electronic apparatus according to claim 1, wherein the number of the heat-conducting units is possible to be plural, a plurality of sets of heat-conducting units are additionally provided on each heat-generating source when the number of the heat-generating sources in the electronic apparatus is increased, thereby performing the heat dissipation for each heat-generating source.

3. The water-cooling heat-dissipating module of an electronic apparatus according to claim 2, wherein the heat-conducting unit is one that is provided therein with a water-guiding fan.

4. The water-cooling heat-dissipating module of an electronic apparatus according to claim 1, wherein a driving unit is additionally provided at a front end of the water-injecting pipe of the dissipating unit, thereby increasing the flowing efficiency of the fluid.

5. The water-cooling heat-dissipating module of an electronic apparatus according to claim 1, wherein a water-guiding notch is provided at an adjacent portion between the water-guiding fan and each blade.

6. The water-cooling heat-dissipating module of an electronic apparatus according to claim 1, wherein the bottom of the spindle of the water-guiding fan penetrates through a spindle seat of the water-guiding fan of the base.

7. The water-cooling heat-dissipating module of an electronic apparatus according to claim 1, wherein water pipes are used to interconnect each unit.

8. The water-cooling heat-dissipating module of an electronic apparatus according to claim 1, wherein heat-dissipating fins are provided on the dissipating unit, the fluid flows through the water-receiving space to transfer the heat source to the heat-dissipating fins, and the heat-dissipating effect is achieved via the heat-dissipating fins.

9. The water-cooling heat-dissipating module of an electronic apparatus according to claim 1, wherein the heat-dissipating fins provided on the dissipating unit is any one type of heat-dissipating fins.

10. The water-cooling heat-dissipating module of an electronic apparatus according to claim 1, wherein heat-conducting pipes are further provided on the heat-dissipating fins of the dissipating unit.

11. The water-cooling heat-dissipating module of an electronic apparatus according to claim 1, wherein a heat-dissipating fan is further provided on the heat-dissipating fins of the dissipating unit so as to increase the heat-dissipating effect.

12. The water-cooling heat-dissipating module of an electronic apparatus according to claim 1, wherein the dissipating unit is selected from any suitable aspects and has a space for receiving a fluid therein.

13. The water-cooling heat-dissipating module of an electronic apparatus according to claim 1, wherein the number of the fluid-receiving space provided in the dissipating unit is one or plural.

14. The water-cooling heat-dissipating module of an electronic apparatus according to claim 1, wherein if a plurality of fluid-receiving spaces is provided in the dissipating unit, each of these fluid-receiving spaces is an independent space, or alternatively, these fluid-receiving spaces are in fluid communication with one another.

15. The water-cooling heat-dissipating module of an electronic apparatus according to claim 1, wherein the driving unit is combined directly with the water-injecting pipe provided on the cover, and is then connected with the water tank via the water pipe, the fluid is introduced into the driving unit via the water pipe so as to perform the heat dissipation.

16. The water-cooling heat-dissipating module of an electronic apparatus according to claim 1, wherein the chassis is provided with projecting heat-dissipating portions.

17. The water-cooling heat-dissipating module of an electronic apparatus according to claim 1, wherein the projecting heat-dissipating portions provided on the chassis are any one aspect of the heat-dissipating fins.

18. The water-cooling heat-dissipating module of an electronic apparatus according to claim 1, wherein the projecting heat-dissipating portions provided on the chassis are heat-conducting pipes.
